(19) United States
(12) Patent Application Publication
(10) Pub. No.: US 2004/0092050 A1
(43) Pub. Date: May 13, 2004

(54) Method of implanting metallic nanowires or nanotubes on a field emission device by flocking

(75) Inventors: Geoffrey Shuy, Hsinchu (TW); Jong-Hong Lu, Hsinchu (TW); Yu-Wei Chou, Hsinchu (TW); Kuokuang Yeh, Hsinchu (TW); Chung-Ho Tai, Hsinchu (TW); Chih-Ming Chang, Hsinchu (TW)

Correspondence Address: BACON & THOMAS, PLLC, 625 SLATERS LANE, FOURTH FLOOR, ALEXANDRIA, VA, 22314

(73) Assignee: Industrial Technology Research Institute, Hsinchu (TW)

(21) Appl. No.: 10/330,075

(22) Filed: Dec. 30, 2002

(30) Foreign Application Priority Data
Nov. 11, 2002 (TW) 91133085

(51) Int. Cl. H01L 21/00

(52) U.S. Cl. 438/20

(57) ABSTRACT

A method of implanting metallic nanowires or nanotube upon substrate with assistance of an electric field is proposed. The resulting structure having implanted and/or oriented nanowires or nanotubes has excellent electron emission behavior, and thus can be used as the electron field emission source in the application of a field emission display or lighting products.

### FIELD OF THE INVENTION

The present invention provides a technique of implanting a substrate with metallic nanowires or nanotubes by using an auxiliary electrostatic field, the resulting implanted and oriented nanowires or nanotubes can be used as electron emission sites in electron field emission source device such as field emitters in field emission display or electron emission source in lighting products.

### FIELD OF THE INVENTION

In current fabrication process of the electron field emission source device, it is generally recognized that if the degree of the orientation of metallic nanowires or nanotubes upon substrate can be enhanced, the turn-on voltage and the threshold voltage can be so reduced that the demand of power saving can be achieved in the application of modern flat panel display or lighting products.

The assignee of the present application discloses in the Taiwan Patent No. 480537 a method for increasing the field emission current density of carbon nanotube, which comprises: screen-printing a slurry of carbon nanotube on a cathode substrate having a plurality of cathode conductive regions to form a plurality of pixel regions of the carbon nanotube layer; subjecting the cathode substrate to a soft baking treatment; subjecting the cathode substrate to a calcination treatment; and adhering a first surface treatment film on the calcined cathode substrate and peeling off the film to remove materials therefrom, that have a poor adhesion, and to pull up the remaining carbon nanotube that lie on the surface. Preferably, said method further comprises, after applying the soft baking treatment on said cathode substrate, adhering a second surface treatment film on said soft-baked cathode substrate and peeling off the film therefrom to further increase the current density.

However, after the soft baking and calcinations treatments, the carbon nanotubes exposed on the surface of the resulting cathode substrate are only a rather small portion of the total carbon nanotube contained in the abovementioned slurry applied. In other word, large amount of carbon nanotubes, that under the surface of the cathode, are not responsible for electron emission.

Currently, the flocking techniques used in the production of the conventional fluffy carpets, fluffy toys, and fluffy decorations include an electrostatic method and a mechanical beating method. The materials used in traditional flocking equipment are usually limited to the insulating filaments, such as fabrics, or dielectric filaments or insulating filaments mixed with metallic filaments, or dielectric filaments mixed with metallic filaments, but all of the materials having sub-millimeter or micron-meter level of the diameter.

### SUMMARY OF THE INVENTION

The present invention improves on the limits of the conventional electrostatic flocking method where only insulating filaments or dielectric filaments are allowed in flocking process, and provides a modified electric field-assisted flocking method that can be used to implant and orient metallic nanowires or nanotubes on a substrate. The resulting metallic nanowire or nanotube regions produced according to the present invention exhibite excellent electron field emission characteristics and have a great potential to b used as field emitter device in a field emission display. Furthermore, this electric field-assisted metallic nanowire or nanotube implanting technique also has a potential in producing field emission emitters in a large area substrate, and has an advantage of good compatibility with nowadays fabrication process.

The electric field-assisted metallic nanowires or nanotubes implanting technique according to the present invention comprises using the following components: an electrostatic field, a barrier layer, a covering layer, a substrate, and metallic nanowires or nanotubes. The metallic nanowires or nanotubes are the materials to be implanted. The covering layer is for the metallic nanowires or nanotubes to be implanted thereon. The substrate provides structural strength for the covering layer and/or optionally provides the electrical conduction to external surroundings. The barrier layer provides a good insulation condition between said metallic nanowires or nanotubes and the applying electrostatic field. The key of this invention is the introduction of the insulating barrier layer that can enable the metallic nanowires or nanotubes to be lifted to fly and finally implanted upon the covering layer when external electrostatic field is applied.

The substrate implanted with oriented nanowires or nanotubes by the present invention are substantially all located on the surface thereof, i.e. the effective percentage of material usage is nearly 100%. Thus, this invention can greatly reduce the material cost in the fabrication process of electron field emitters in the application of field emission display or lighting. Therefore, the present invention is beneficial to the improvement on the processes in producing field emission panel display or lighting products.

### BRIEF DESCRIPTION OF THE DRAWINGS

The objectives and advantages of the present invention can be better understood through a detailed explanation of the present invention in the following and the accompanied drawings, wherein:

FIG. 1 is a schematic cross sectional view showing a scheme of an electric field-assisted nanowires or nanotubes implanting method according to the present invention, where legends used in the drawing are explained in the following:

10: pre-loaded metallic nanowires or nanotubes

20: substrate

30: covering layer

40: barrier layer

50: electrostatic field

FIG. 2 shows the cross-section scanning electronic microscopy (SEM) photograph of carbon nanotubes implanted on the covering layer according to Example 1 of the present invention.

FIG. 3 shows the I-V characteristics curve of the field emission source obtained from Example 1 of the present invention.

FIG. 4 shows the cross-section scanning electronic microscopy (SEM) photograph of nickel nanowires implanted on the covering layer according to Example 2 of the present invention.

FIG. 5 shows the I-V characteristics curve of the field emission source obtained from Example 2 of the present invention.

### DETAILED DESCRIPTION OF THE INVENTION

The present invention provides a method for implanting a substrate with oriented nanowires or nanotubes, which can be used in the production of a field emission source device. The invented method comprises the following steps:

a) spreading nanowires or nanotubes on a barrier layer;

b) disposing a substrate having a covering layer so that the covering layer is facing the nanowires or nanotubes, and that the covering layer is parallel to and spaced from the barrier layer;

c) applying a electrostatic field to the resulting space between said barrier layer and said substrate, so that said nanowires or nanotubes are lifted to fly from said barrier layer and implanted on the covering layer;

wherein said barrier layer comprises a single layer structure of a semiconductive or insulating material, or a multilayer structure of a combination thereof to provide the nanowires or nanotubes with insulation; said covering layer has a rigidity smaller than that of the nanowires or nanotubes for allowing the nanowires or nanotubes to be implanted on said covering layer in the presence of said electrostatic field, wherein said covering layer is made of a polymeric material, a metallic material, a semiconductive material, an insulating material, or a mixture of a polymer and a metallic material.

Preferably, said nanowires or nanotubes are metallic nanowires or nanotubes; a mixture of metallic and insulating nanowires or nanotubes; a mixture of metallic and semiconductive nanowires or nanotubes; or a mixture of metallic, semiconductive, and insulatiing nanowires or nanotubes. More preferably, said nanowires or nanotubes are carbon nanotubes or nickel nanowires.

Preferably, said substrate comprises a single layer structure of a metallic, semiconductive or insulating material, or a multilayer structure of a combination of two or three materials selected from the group consisting of the metallic, semiconductive and insulating materials. More preferably, said substrate is a copper foil, aluminum oxide or silicon substrate.

Preferably, said electrostatic field is applied by applying a direct voltage differences on a structure of two electrodes or multi-electrodes formed by metal plates, metal tips in an array, matrix or a combination of them.

Preferably, said covering layer is a conductive adhesive or a soft insulating adhesive film.

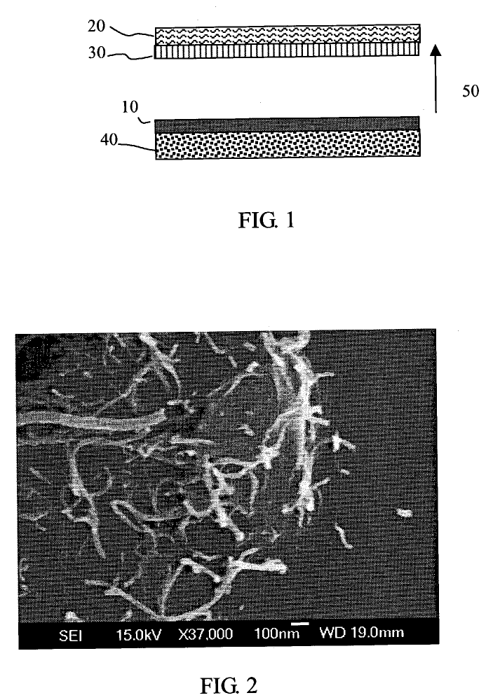

As shown in FIG. 1, an implementation scheme for carrying out a method according to the present invention comprises: an externally applied electrostatic field 50, a barrier layer 40, a covering layer 30, a substrate 20, and pre-loaded nanowires or nanotubes 10. The pre-loaded nanowires or nanotubes 10 are the material to be implanted. The substrate 20 and the covering layer 30 are combined together to provide a structural strength and optionally an electric conducting media. The covering layer 30 is to be implanted with the metallic nanowires or nanotubes 10. The barrier layer 40 provides insulation between the metallic nanowires or nanotubes 10 and the electrostatic field 50, so that the metallic nanowires or nanotubes 10 can be lifted therefrom due to the action of the electric field 50. A modulation of the electric field can be used to control the lifting, orientation and implantation of the pre-loaded metallic nanowires or nanotubes 10.

The characteristics and effects of the present invention will be elaborated in detail by the following examples, which are for illustrative purpose only and not for limiting the scope of the present invention.

### EXAMPLE 1

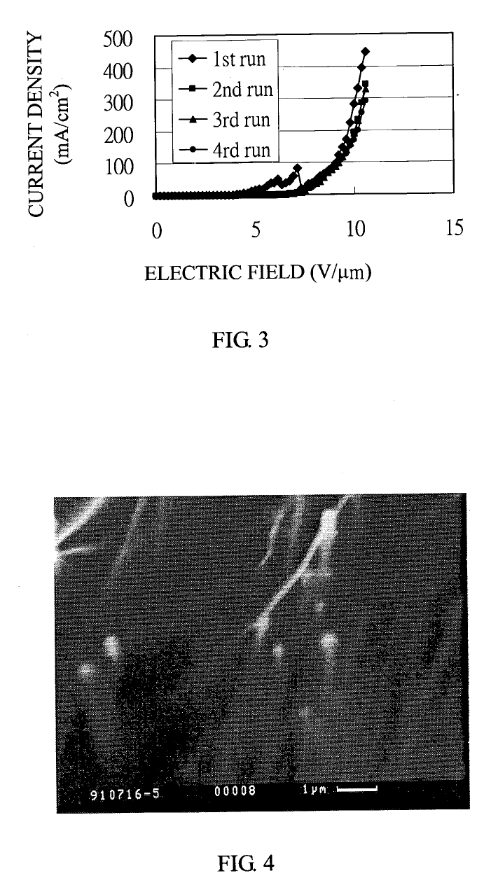

The scheme as shown in FIG. 1 was used to carry out this example. Two parallel electrode plates were used to generate an external electrostatic field 50 having approximately an electric field intensity of 800 V/cm. The barrier layer 40 was an insulating acrylate having a thickness of about 2 mm. The covering layer 30 was a soft epoxy resin adhesive having a thickness of about 20 μm. The substrate 20 was an electric conducting copper foil. The material of the pre-loaded metallic nanowires or nanotubes 10 was a metallic multi-walled carbon nanotube. The distance between the covering layer 30 and the barrier layer 40 was 10 cm. FIG. 2 shows the SEM picture of carbon nanotubes implanted on the soft covering layer. This figure indicated that carbon nanotubes are implanted. FIG. 3 shows the I-V characteristics curve measured by using a sample prepared in Example 1 as a field emitter. The results imply that the implanted carbon nanotubes penetrate the soft covering layer under the influence of the externally applied electrostatic field, and come into contact with the electrically conductive substrate. The measured I-V characteristics indicate that the substrate flocked with the carbon nanotubes can be used as a field emitter in the application of field emission display.

### EXAMPLE 2

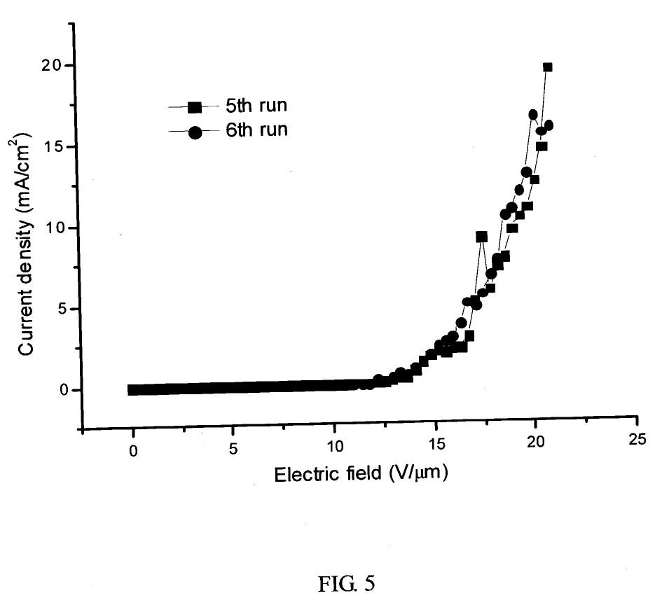

The scheme shown in FIG. 1 was used to implement this example. Two parallel electrode plates were used to generate an electrostatic field 50 having an electric field intensity of about 1000 V/cm. The barrier layer 40 was an insulating acrylate having a thickness of about 2 mm. The covering layer 30 was an electrically conductive silver paste having a thickness of about a few hundreds micro-meters. The substrate 20 was made of aluminum oxide. The pre-loaded metallic nanowires or nanotubes 10 were nickel nanowires. The distance between the covering layer 30 and the barrier layer 40 was 10 cm. FIG. 4 shows the SEM picture of nickel nanowires oriented on the soft covering layer. FIG. 5 shows the I-V characteristics measured by using a sample prepared in this example as a field emitter.

1. A method for implanting a substrate with nanowires or nanotubes in the fabrication of electron field emission source device, which comprises the following steps:
a) spreading nanowires or nanotubes on a barrier layer;
b) disposing a substrate having a covering layer so that the covering layer is facing the nanowires or nanotubes, and that the covering layer is parallel to and spaced from the barrier layer;
c) applying a electrostatic field to the resulting space between said barrier layer and said substrate, so that said nanowires or nanotubes are lifted from said barrier layer and implanted on the covering layer;
wherein said barrier layer comprises a single layer structure of a semiconductive or insulating material, or a multilayer structure of a combination thereof to provide the insulation condition; said covering layer has a rigidity smaller than that of the nanowires or nanotubes for allowing the nanowires or nanotubes to be implanted on said covering layer in the presence of said electrostatic field, wherein said covering layer is made of a polymeric material, a metallic material, a semiconductive material, an insulating material, or a mixture of a polymer and a metallic material.

2. The method as claimed in claim 1, wherein said nanowires or nanotubes are metallic nanowires or nanotubes; a mixture of metallic and insulating nanowires or nanotubes; a mixture of metallic and semiconductive nanowires or nanotubes; or a mixture of metallic, semiconductive, and insulating nanowires or nanotubes.

3. The method as claimed in claim 1, wherein said substrate comprises a single layer structure of a metallic, semiconductive or insulating material, or a multilayer structure of a combination of two or three materials selected from the group consisting of metallic, semiconductive and insulating materials.

4. The method as claimed in claim 1, wherein said electrostatic field is applied by applying a direct voltage difference on a structure of two electrodes or multi-electrodes formed by metal plates, metal tips array or matrix or a combination of them.

5. The method as claimed in claim 2, wherein said nanowires or nanotubes are carbon nanotubes or nickel nanowires.

6. The method as claimed in claim 3, wherein said substrate is a copper foil, aluminum oxide or silicon substrate.

7. The method as claimed in claim 1, wherein said covering layer is a conductive adhesive or a soft insulatiing adhesive film.
